(19) United States
(12) Patent Application Publication
(10) Pub. No.: US 2017/0012642 A1
(43) Pub. Date: Jan. 12, 2017

(54) METHOD FOR DECODING NON-BINARY CODES AND CORRESPONDING DECODING APPARATUS

(71) Applicants: CENTRE NATIONAL DE LA RECHERCHE SCIENTIFIQUE (CNRS), Paris (FR); UNIVERSITE CERGY-PONTOISE, Cergy (FR); UNIVERSITAT POLITÈCNICA DE VALÈNCIA, Valencia (ES)

(72) Inventors: David Declercq, Ableiges (FR); Erbao Li, Zhengzhou (CN); Francisco Miguel Garcia Herrero, Gandia (ES); Javier Valls Coquillat, Tavernes De La Valldigna (ES)

(73) Assignees: Centre National de la Recherche Scientifique (CNRS ), Paris (FR); Universite Cergy-Pontoise, Cergy (FR); Universitat Politècnica de València, Valencia (ES)

(21) Appl. No.: 15/116,291

(22) PCT Filed: Feb. 3, 2015
(86) PCT No.: PCT/EP2015/052206

§ 371 Date: Aug. 3, 2016

(30) Foreign Application Priority Data
Feb. 3, 2014 (EP) 14290024.0

(51) Int. Cl. H03M 13/11

(52) U.S. Cl. CPC H03M 13/1108; H03M 13/1171

(57) ABSTRACT

An extension to the enhanced serial generalized bit-flipping decoding algorithm (ES-GBFDA) of non-binary LDPC codes by introducing soft information in the check node operation. The application not only considers the most reliable symbol in the syndrome computation, but also takes at least the second most reliable symbol of each incoming message into account. An extended information set is available for the parity-check node update and this allows introducing the concept of weak and strong votes performed by the check node unit. Each variable node can receive two kinds of votes, whose amplitudes can be tuned to the reliability of the syndrome that produces the vote.

### FIELD OF THE INVENTION

The invention concerns the decoding of error correcting codes in the field of telecommunications and data storage. More specifically the invention concerns a decoding method and the corresponding decoder for non-binary Low-Density Parity Check (LDPC) codes.

### BACKGROUND

The design of high-throughput decoders for non-binary low-density parity-check (NB-LDPC) codes in GF(q), with moderate silicon area, is a challenging problem, which requires both low complexity algorithms and efficient architectures.

Algorithms derived from the q-ary sum-product (QSPA) [1], [2], [3], [4] such as extended min-sum (EMS) [5] and min-max (Min-Max) [7] involve high complexity in their check node units (CNU), that implement the parity-check node update equations. In particular, the CNU of the different versions of EMS or Min-Max requires many comparisons, which reduce the maximum achievable throughput, due to a large inherent latency. This high latency is a bottleneck, especially for the decoding of high rate NB-LDPC codes (R>0.8), where the parity-check node degree c takes large values. Techniques like forward-backward implementation of the CNU [8], [10] or the bubble check algorithm [9] can reduce the latency to a minimum of dc clock cycles, with enough hardware parallelism, but this is still not sufficient to reach very high throughput. As a result, the architectures based on EMS or Min-Max algorithms [13], [14], [15] can achieve coding gains close to QSPA, but at the cost of low decoding throughput.

Aside from the EMS or Min-Max like algorithms, other solutions have been proposed in the literature, with the objective of greatly reducing the decoding complexity at the cost of larger performance loss compared to QSPA. The architectures that can achieve high throughput, and at the same time use a small chip area, just compute a very small set of parity check equations during the parity-check node update. This approach has been followed for majority-logic decodable (MD) algorithm [11] and generalized bit flipping-decoding algorithm (GBFDA) [12]. These simple algorithms, and the associated architectures [21], [17], [18] suffer from a non-negligible performance loss compared to the QSPA, between 0.7 dB to several dBs depending on the algorithm and the LDPC code. This performance loss is due to the lack of soft-information used in the CNUs of GBFDA and MD, and cannot be recovered with a larger number of decoding iterations [18]. In addition, GBFDA and MD tend to be more efficient for codes with medium variable node degrees (dᵥ>3 in the case of GBFDA), and do not perform well for ultra-sparse dᵥ=2 NB-LDPC codes, which have been identified as an important class of non-binary codes [6].

### SUMMARY OF THE INVENTION

The invention permits to improve the performance of the decoding of a non-binary low density parity-check (NB-LDPC).

To this end the invention concerns a method for decoding a non-binary low density parity-check code defined in a finite field of size q, the code can be displayed in a bipartite graph comprising at least one variable node Vₙ, n=0, . . . , N−1 and at least one check node Cₘ, m=0, . . . , M−1, said method comprising for each iteration j of Iₜ decoding iterations, the steps consisting in that:

each variable node Vₙ, connected to a check node Cₘ, is configured for determining a most reliable symbols Qₙ^{1(j)} and at least one symbol which is at least a p^{th} most reliable symbol Qₙ^{p(j)}, with p≧2 for obtaining a vector of dc most reliable symbols;

each check node Cₘ is configured for determining:
a first symbol to be voted Rₙ^{0(j)}=Rₙ^{(j)} based on the vector of d_{c} most reliable symbols passed by the variable nodes connected to him in the bipartite graph;
a list of i=1, . . . , L second symbol to be voted Rₙ^{i(j)} based on a list of L+1 test vectors defined as a combination of d_{c} symbols with a restriction according to which at most η of these d_{c} symbols are a p^{th} most reliable symbol Qₙ^{p(j)} with p≧2, and at least d_{c}−η of these symbols are a most reliable symbol Qₙ^{1(j)}.

The method according to the invention may have one of the following features:

Each variable node is configured for determining the most reliable symbols Qₙ^{(j)} and the second most reliable symbol Qₙ^{2(j)}=Q′ₙ^{(j)} and their corresponding extrinsic reliability ΔWₙ^{(j)}, ΔW′ₙ^{(j)} so that at a check node the list of L+1 test vectors are built by replacing symbol Qₙ^{(j)} by the second most reliable symbol Q′ₙ^{(j)} in at most η≦L locations were the differences between ΔWₙ^{(j)} and ΔW′ₙ^{(j)} are the smallest.

For η≦L, it comprises a step consisting in that a sorter unit is configured for sorting the differences of extrinsic reliability Δₙₘ^{(j)-ΔW}ₙₘ^{2(j)} from the highest value to the lowest value for obtaining a sequence [symbol] of L sorted indices n, the sequence [symbol] comprising the η locations where Qₙ^{(j)} is replaced by Qₙ^{2(j)} in the L+1 test vectors.

Each variable node is further configured for computing an intrinsic information Wₘₙ^{(j)} from check node counting the votes of Rₙ^{0(j)} and of Rₙ^{i(j)} with the respectively amplitude voting v₀, v₂.

It comprises before the Iₜ decoding iterations an initialization step comprising the sub-steps of:

determining a LLR vector Lₙ=(Lₙ[0], Lₙ[1], . . . , Lₙ[q−1]) of a n^{th} symbol in a sequence of N non-binary noisy symbols;

initializing a vector of APP vectors Wₙ⁽⁰⁾ to the LLR vector Lₙ and initializing a matrix Wₘₙ⁽⁰⁾ to an all-zero matrix, said matrix Wₘₙ^{(j)} being the intrinsic information from the check node m.

Each variable node taking as input the LLR vector and the vector Wₘₙ^{(j)} combines the previous vector Wₘₙ^{(j-1)}, the voting symbols Rₙ^{0(j)} and of R′ₙ^{(j)} and the voting amplitudes v₀, v₁ through a function F₁ for obtaining the vector defined as the intrinsic information Wₘₙ^{(j)}.

The function F₁ is a simple summation of the values of the previous vector Wₘₙ^{(j-1)} at indices indicated by the voting symbols Rₙ^{0(j)} and of R′ₙ^{(j)} and the voting amplitudes v₀, v₁.

The LLR vector and the vector Wₙ^{(j)} combines (A5.1, A5.2) the previous vector wₙ^{(j-1)} Wₘₙ^{(j-1)}, the voting symbols Rₙ^{0(j)} and of Rₙ^{i(j)} and the voting amplitudes v₀, v₁ through a function F₂ for obtaining the vector Wₙ^{(j)}.

The function F₂ is a simple summation of the values of the previous vector Wₙ^{(j-1)} at indices indicated by the voting symbols Rₙ^{0(j)} and of Rₙ^{i(j)} and the voting amplitudes v₀, v₁.

The invention also concerns, a decoding apparatus comprising at least one variable node Vₙ and a at least one check node Cₘ, said decoder being configured for implementing a method for decoding a non-binary low density parity-check code defined in a finite field of size q, according to the invention.

The decoding apparatus of the invention may have one of the following features:

It is configured for implementing check node operations by means of L processing units configured dynamically to compute Rₙ^{i(j)}, with i=1, . . . , L, each one of the L processing units share 3×d_{c} inputs that correspond to the symbols Qₙ^{1(j)}, Qₙ^{2(j)} and to the coefficients of the code, said inputs of each processing unit are combined by means of 2×d_{c} GF multipliers and 2×d_{c} GF adders, said processing units including all the logic necessary to compute L different syndromes as an intermediate step and a variable number of pipeline stages that may vary from 0 to log 2(d_{c})+2 depending on the speed of said processing unit.

It is configured for implementing the method of the invention and comprises i) a bank of memories that store Rₙ^{i(j)}, with i=0, . . . , L symbols, ii) q processors with a logic required to compare the symbols Rₙ^{i(j)}, with i=0, . . . , L, with the q elements of the Galois Field and determine the amplitude of the votes corresponding to that symbols; and iii) q cells that implement functions F₁ and F₂ , the bank of memories being implemented with L RAM memories or a bank of L registers., the processors being implemented with L-XNOR gates of log 2(q) bits and L-OR gates of 1 bit to compare the input symbols (symbols Rₙ^{i(j)}, with i=0, . . . , L,) with the q Galois Field elements and determine the amplitude of the votes, the cells including a logic necessary for implementing F₁ and F₂ and the storage resources for Wₘₙ^{(j)} and Wₙ^{(j)}.

It comprises a sorter unit configured for obtaining the sequence N² of L sorted indices n according to the method of the invention, the sorter unit including at least one sub-processors of radix L, each sub-processor including: i) one stage of comparators configured for performing all the possible combinations of the inputs; ii) a plurality of adders and a plurality of NOT gates configured for computing a summation of the output signals of the different comparators associated to the same input, the adders being configured for checking how many times a condition of greater than or less than is satisfied for each one of the inputs; iv) a plurality of logic gates configured for implementing a L different masks that allows ordering the inputs according to the information provided by the outputs of the adders, logic gates are XNOR, OR and AND gates. The invention permits to achieve both a high throughput and a coding gain as close as possible to QSPA, by taking advantage of the low complexity of GBFDA operations and introduces soft information in the CNU, as it is done in EMS and Min-Max, to improve the coding gain. The core idea of the ES-GBFDA CNU is to compute the syndrome using the hard decisions on the symbols, obtained from the most reliable Galois field values, and declare a vote for the hard decision symbols which satisfy the parity-check. The vote is then propagated to the symbol nodes and accumulated along the decoding iterations in a memory.

Contrary to ES-GBFDA, the invention not only considers the most reliable symbols in the syndrome computations, but also to take at least the second most reliable symbols (in each incoming message) into account. By doing so, an extended information set is available for the parity-check node update and this allows introducing the concept of weak and strong votes, performed by the CNU, and propagated to the symbol node memory. With this feature, each variable node can receive two kinds of votes, whose amplitude can be tuned to the reliability of the syndrome that produces the vote.

For this reason, the decoding method of the invention can be called multiple-vote symbol-flipping decoder (MV-SF).

At the MV-SF CNU, we call test vector a set of symbols taken from the most reliable and the second most reliable symbols of each incoming message. The invention introduces some extra soft-information and enlarges the list of considered test vectors, therefore, improving the decoding performance. Meanwhile, the complexity of the CNU for each extra test vector is the same as GBFDA, which gives the method of the invention the nice feature of controlling the performance/complexity trade-off: the more test vectors are considered, the better the performance is, and the less test vectors are considered, the better the throughput is.

As an example, a decoder with four times more test vectors than the ES-GBFDA, on a (N=837, K=723) NB-LDPC code over GF(32), shows a coding gain of 0.44 dB compared with GBFDA and has just a performance loss of 0.21dB compared to Min-Max. Moreover, the associated architecture can reach a throughput similar to the ES-GBFDA [18] with an increase of area less than two times, not four times as expected from a direct architecture mapping.

The invention improves the coding gain of ES-GBFDA by creating a list of test vectors that increases the amount of soft information in the check node update. The variable node is also modified to introduce different amplitudes in the votes involved in the computation, with the objective of distinguishing if the vote is produced by the most reliable information or by both most and second most reliable symbols. With the invention, the gap of performance between ES-GBFDA and Min-Max or EMS is reduced.

Derived from the method of the invention, a high throughput architecture of a decoder is proposed. Area required is less than L/2 times area of the ES-GBFDA, being L the size of the list of test vectors. This fact demonstrates the optimization of the architecture, which does not increase its area L times, as it would be the case of a direct mapping solution. The invention, even overestimating area, reaches at least 27% more efficiency (throughput/area) compared to the best Min-Sum and Min-Max architectures, with the cost of only 0.21dB performance loss. The invention based on GBFDA can reach similar performance to EMS and Min-Max, but with the advantage of higher throughputs.

### BRIEF DESCRIPTION OF THE DRAWINGS

Other features and advantages of the invention will appear in the following description with references to the drawings, in which:

FIG. 1a illustrates a bipartite graph of the method of the invention;

FIG. 1b illustrates a single variable node of the method of the invention;

FIGS. 1c and 1d illustrate a single check node of the invention;

FIG. 2 illustrates a structure to generate the L sorted indices in the method of the invention;

FIG. 3 illustrates a variable node receiving information from a check node according to the invention;

FIG. 4 illustrates an architecture of a decoder of the invention;

FIGS. 5a and 5b illustrate architecture of check node units of the decoder of the invention;

FIG. 6 illustrates architecture of variable node units of the decoder of the invention;

FIG. 7 illustrates a CELL of variable node units of the decoder of the invention;

FIG. 8 illustrates a general architecture for a sorter unit of the invention for a 4-minimum finder in a 27 element list;

FIGS. 9a and 9b illustrate an architecture for the first stage (I=0) of the sorter unit of FIG. 8;

FIG. 10 illustrates architecture for stages different from the first (I>0) of the sorter unit of FIG. 8;

FIG. 11 illustrates theoretical estimation of area-complexity for the decoder of the invention based on a message passing architecture;

FIG. 12 illustrates theoretical estimation of area-complexity for R minimum finder in a dc list.

### DETAILED DESCRIPTION

A method for decoding a non-binary low density parity-check (NB-LDPC) code defined in a finite field of size q is based on a bipartite graph comprising at least one variable node Vₙ, n=0, . . . , N−1 and at least one check nodes Cₘ, m=0, . . . , M−1.

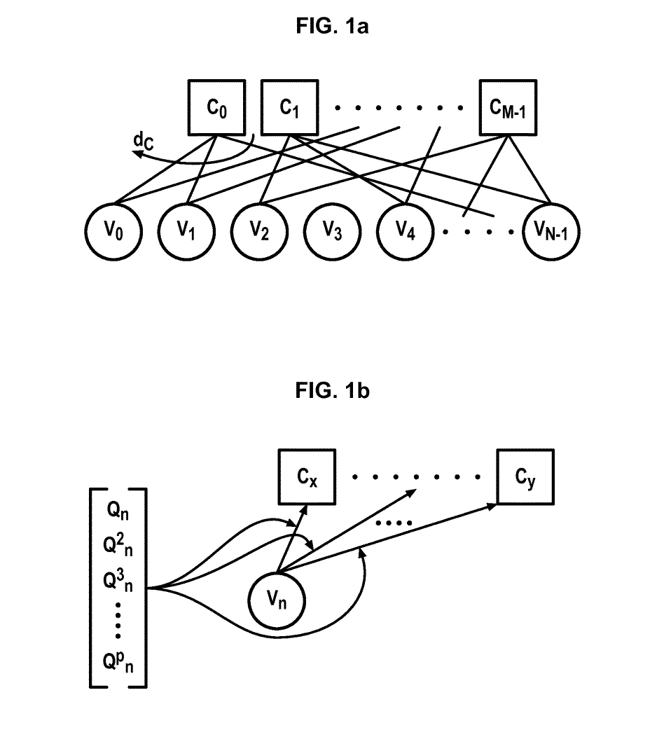

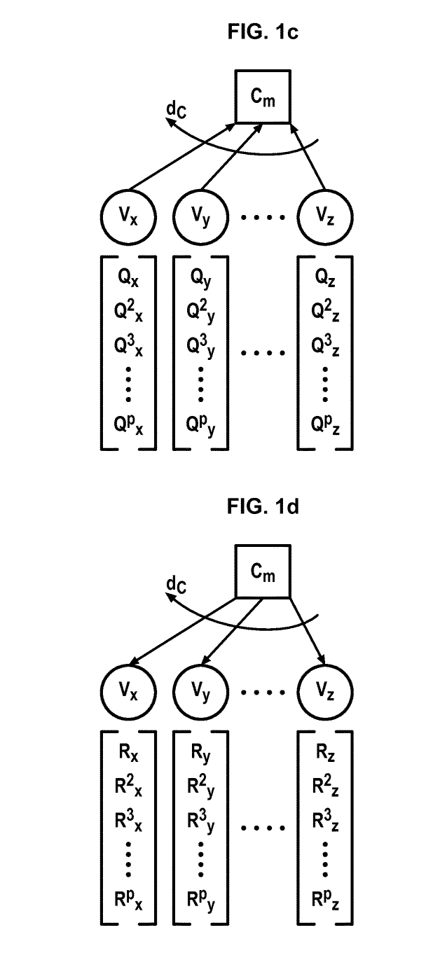

FIG. 1a illustrates a bipartite graph with M check nodes Cₘ, m=0, . . . , M−1 and N variable nodes Vₙ, n=0, . . . , N−1. As shown on this figure, each check node Cₘ is connected to d_{c} variables nodes Vₙ.

### NB-LDPC Notations

Let us define a (N,K) NB-LDPC code over GF(q) (q=2^{p}) with code length N and information length K. Its parity check matrix H_{M,N} has N columns and M rows. The non-zero coefficients of H_{M,N} are h_{m,n}, where m is the row index and n the column index. The check node degree is denoted as d_{c} and the variable node degree as dᵥ, [symbol] (m) defines the set of variables nodes connected to the m-th check node, and [symbol] (m) the set of check nodes connected to the n-th variable node. After transmission over a noisy Additive White Gaussian Noise (AWGN) channel, the received symbol sequence is defined as Y=(y₀,y₁, . . . , y_{N-1}). Considering the transmission of the codeword symbol cₙ, the log-likelihood ration (LLR) is computed as Lₙ[x]=log [P(cₙ=0)|yₙ)/P(cₙ=x|yₙ)], for each x ∈ GF(q). The LLR vector of the n-th symbol is Lₙ=(Lₙ[0], Lₙ[1], . . . , Lₙ[q−1]). The hard-decision based on the most reliable element in Lₙ is called zₙ ∈ GF(q).

### Enhanced Serial GBFDA (ES-GBFDA)

The method for decoding a NB-LDPC code according to the invention is an improvement of the ES-GBFDA. Before explaining the method of the invention we briefly describe this known improved algorithm, especially the ES-GBFDA from [18] called “Algorithm 1” above.

In this Algorithm 1, two main steps can be distinguished in the iterative process the check node unit (CNU), steps A2 and A3; and the variable node unit (VNU), steps A1, A4 and A5.

During the initialization, Wₙ⁽⁰⁾ equals to the channel LLRs, Lₙ, and Wₘₙ⁽⁰⁾ is an all-zero matrix. After initialization, at the j-th iteration, step A1 sorts the extrinsic information to find the symbols Qₙ^{(j)} with the maximum reliability (GFmax), which will be taken as the new hard decision.

The extrinsic information is calculated as Wₙ^{(j-1)}−Wₘₙ^{(j-1)}·Wₙ^{(j-1)} is the vector where all the votes are accumulated and the Wₘ^{(j-1)} is the intrinsic information from check node Cₘ. Step A2 computes the syndrome s, required in step A3 to calculate Rₙ^{(j)}, which is the symbol to be voted (selected). In step A4, Wₘₙ^{(j)} counts the votes on Rₙ^{(j)} where v is the amplitude of the vote. In step A5, Wₙ^{(j)} accumulates the initial LLRs plus the votes of all the check nodes connected to the variable node Vₘ. The votes modify the values of Wₙ^{(j-1)} and Wₘₙ^{(j-1)}, changing the result of the sorting process in A1 and, hence, flipping symbols in Qₙ^{(j)}. Step A6 performs the tentative decoding by finding the symbols associated to the maximum values of Wₙ^{(j)} and step A7 implements the stopping criterion based on the information of all the syndromes. The decoded codeword is then \tilde{c}ₙ^{(j)}.

Algorithm 1. Serial Enhanced-GBFDA

```
Initialization: Wₙ⁽⁰⁾ = Lₙ, Wₘₙ⁽⁰⁾ = 0
For j = 1 to Itₘₐₓ
  For m = 1 to M
  A1 : Qₙ^{(j)} = GFmax(Wₙ^{(j-1)} − Wₘₙ ^{(j-1)})
  A2 : s = Σ_{n∈N(m)} h_{m,n}Qₙ^{(j)}
  A3 : Rₙ^{(j)} = hₘₙ⁻¹s − Qₙ^{(j)}
  A4 : Wₘₙ^{(j)}(Rₙ^{(j)}) = Wₘₙ^{(j-1)}(Rₙ^{(j)}) + v
  A5 : Wₙ^{(j)}(Rₙ^{(j)}) = Wₙ^{(j-1)}(Rₙ^{(j)}) + v
  end For m
  A6 : \tilde{c}ₙ^{(j)} = GFmax(Wₙ^{(j)})
  A7 : if (\tilde{c}ₙ^{(j)} × H^{T} = 0) SKIP
end For j
Output= \tilde{c}ₙ^{(j)}
```

### General Presentation of the Method of the Invention Called as Multiple Vote Symbol Flipping Decoding Algorithm (MV-SF)

We now describe, in a general way, the method of the invention based on the ES-GBFDA, by increasing the list of candidates computed by each check node and hence, increasing as well the number of votes propagated to the variable node. We only present the steps involved at the j-th decoding iteration.

Let Qₙ^{(j)} be the hard decision obtained from the most reliable symbols, and Qₙ^{p(j)} the hard decision of the p-th most reliable symbol within the input messages of a check node cₘ. We only consider the most reliable symbol Qₙ^{(j)} and the second most reliable symbol Qₙ^{2(j)}=Q′ₙ^{(j)}. The symbols Qₙ^{(j)} (respectively Qₙ^{2(j)}) are associated with reliabilities ΔWₙ^{(j)} (respectively ΔWₙ^{2(j)}=ΔW′ₙ^{(j)}).

We define test vector for a check node cₘ as the combination of d_{c} symbols with the restriction that at least one, and at most η of these d_{c} symbols cannot be based on the most reliable information. In order to reduce the number of test vector candidates we only consider combinations between Qₙ^{(j)} and Q′ₙ^{(j)}. To build the list of test vectors of a check node cₘ, first the difference between the reliability of ΔWₙ^{(j)} and ΔW′ₙ^{(j)} is computed and sorted in ascendant order for n ∈ [symbol] (m). The first elements of the sorted differences are the symbols in which the reliability of Q′ₙ^{(j)} is closer to the reliability of Qₙ^{(j)}. To keep the number of test vectors low we only replace Qₙ^{(j)} by Q′ₙ^{(j)} in at most η locations were the differences between ΔWₙ^{(j)} and ΔW′ₙ^{(j)} is smaller (first η elements of the sorted list). The parameter η tunes the performance/complexity trade-off of the algorithm since it is directly related to with the number of test vectors to be processed by each check node. η is selected as η<<d_{c} to keep complexity low. The set with the η locations is denoted [symbol] ′.

Let us define Γᵢ^{(j)} as the i-th test vector of a list 2^{η}−1 possible test vectors of a check node m, different from the one based only on Qₙ^{(j)} symbols. Each Γᵢ^{(j)} is built replacing Qₙ^{(j)} with Q′ₙ^{(j)}.

In Equation (1) the definition of the test vector Γᵢ^{(j)} is indicated where [symbol] ′ₜ is the t-th element in the set [symbol] ′, iₜ is the bit t of the binary representation of i and i̅ₜ̅ is the complementary value. Operator [symbol] and ⊕ are the ‘AND’ and ‘OR’ operations respectively.

$${Γ}_{i}^{( j )} ∈ \{ {Q}_{n}^{( j )} , {Q}_{{𝒩}_{t}^{′}}^{′ ( j )} ⊗ {i}_{t} ⊕ {Q}_{{𝒩}_{t}^{′}}^{( j )} ⊗ \overline{{i}_{t}} \} , \\ n ∈ 𝒩 ( m ) \backslash {𝒩}^{′} , t = 0 to η - 1 \qquad ( 1 )$$

In the same way, we can define the reliability of each Γᵢ^{(j)}, ωᵢ^{(j)}, by means of Equation (2).

$${ω}_{i}^{( j )} = {\sum }_{n ∈ 𝒩 ( m ) \backslash {𝒩}^{′}} Δ {W}_{n}^{( j )} + {\sum }_{t = 0 \text{:} η - 1} Δ {W}_{{N}_{t}^{′}}^{′ ( j )} \times {i}_{t} + Δ {W}_{{N}_{t}^{′}}^{( j )} \times {\overline{i}}_{t} \qquad ( 2 )$$

### Description of a Preferred Embodiment of the Method of the Invention

We now consider a case wherein each check node is composed of L=η test vectors. Each test vector has d_{c}−1 Qₙ^{(j)} symbols, and one Q′ₙ^{(j)} symbol. The position of the Q′ₙ^{(j)} symbol in the test vector i, Γᵢ^{(j)} is given by N′ᵢ as follows:

$${Γ}_{i}^{( j )} ∈ \{ {Q}_{n}^{( j )} , {Q}_{{𝒩}_{i}^{′}}^{′ ( j )} \} , n ∈ 𝒩 ( m ) \backslash {𝒩}_{i}^{′} \qquad ( 3 )$$

The reliability equation for the test vector Γᵢ^{(j)} is given by

$${ω}_{i}^{( j )} = {\sum }_{n ∈ 𝒩 ( m ) \backslash {𝒩}_{t}^{′}} Δ {W}_{n}^{( j )} + Δ {W}_{{𝒩}_{t}^{′}}^{′ ( j )} \qquad ( 4 )$$

It can be deduced from Equation (4) that changing Qₙ^{(j)} by Q′ₙ^{(j)} in N′ᵢ does not introduce a strong variation in the total reliability of the check node, ωᵢ^{(j)}. The only element that changes in the sum is

$$Δ {W}_{{N}_{i}^{′}}^{( j )} ,$$

which is selected because the difference

$$Δ {W}_{{N}_{i}^{′}}^{( j )} - Δ {W}_{{N}_{i}^{′}}^{′ ( j )}$$

is one of the η smallest (so both

$${Q}_{{N}_{i}^{′}}^{( j )} and {Q}_{{N}_{i}^{′}}^{′ ( j )}$$

have similar reliabilty in the selected location N′₁).

In other words, as Γᵢ^{(j)} has a high reliability, similar to Qₙ^{(j)}, processing its candidates increases the amount of useful soft-information in the decoder and hence improves the performance.

To keep the complexity low and avoid computing and storing (4) for each test vector, function [symbol] (ωᵢ^{(j)}) has to be very simple.

In a preferred embodiment of the invention, only two amplitudes for the votes are considered vₒ for the symbol candidates derived from the most reliable test vector, and v₁ for the other test vectors, v₀>v₁. However, this latter condition for the amplitudes v₀ and v₁ is necessary but not sufficient to obtain the best efficiency and performance. As already mentioned, the distance between the amplitudes is, with 7₇, the most important parameter to be optimized. If v₀ and v₁ are too close the amplitudes of the votes will be mixed easily and the flipping of the symbols will be done almost without any criterion, as candidates with very different reliability values will have almost the same vote amplitude. If the difference between v₀ and v₁ is too large, the votes of the less reliable test vectors will be not taken into account and the effect will be similar as not having an extended list of candidates. On the other hand, the values vₒ and v₁ also have to be scaled according to the channel information. Unlike other algorithm as EMS or Min-max were all the information is strongly related with the incoming LLRs, algorithms based on voting process mix two different domains, the one with channel information and the one based on votes. It is easy to deduce that some kind of normalization is required for vote amplitudes or for channel information in order to combine them properly. Hence, we need to optimize the amplitudes of the votes v₀ and v₁, and also their combination with the LLR information, through the function [symbol] .

In the preferred embodiment of the invention called “Algorithm 2” above, L=η. It can be seen that some steps of this Algorithm 2 are similar to some steps of Algorithm 1 (i.e., ES-GBFDA).

Algorithm 2. Multiple-Vote Symbol Flipping Decoding Algorithm
$Initialization \text{:} {W}_{n}^{( 0 )} = {L}_{n} , {W}_{mn}^{( 0 )} = 0 , \\ L = size of the expanded list$ $For j = 1 to {It}_{max}$ $For m = 1 to M$ $A 1.1 \text{:} Δ {W}_{n}^{( j )} = {max}_{0} ( {W}_{n}^{( j - 1 )} - {W}_{mn}^{( j - 1 )} )$ ${Q}_{n}^{( j )} = {GFmax}_{0} ( {W}_{n}^{( j - 1 )} - {W}_{mn}^{( j - 1 )} )$ $A 1.2 \text{:} Δ {W}_{n}^{′ ( j )} = {max}_{1} ( {W}_{n}^{( j - 1 )} - {W}_{mn}^{( j - 1 )} )$ ${Q}_{n}^{′ ( j )} = {GFmax}_{1} ( {W}_{n}^{( j - 1 )} - {W}_{mn}^{( j - 1 )} )$ $A 1.3 \text{:} {𝒩}^{′} = IndexSortAscendant ( Δ {W}_{n}^{( j )} - Δ {W}_{n}^{′ ( j )} ) , n ε N ( m )$ $A 2.1 \text{:} s = {\sum }_{n ε 𝒩 ( m )} {h}_{m , n} {Q}_{n}^{( j )}$ $A 2.2 \text{:} For i = 1 to L$ ${s}_{i}^{′} = s - {h}_{m , {𝒩}_{i}^{′}} {Q}_{n}^{( j )} + {h}_{m , {𝒩}_{i}^{′}} {Q}_{{𝒩}_{i}^{′}}^{′ ( j )}$ $end For i$ $A 3.1 \text{:} {R}_{n}^{( j )} = {h}_{nm}^{- 1} s - {Q}_{n}^{( j )}$ $A 3.2 \text{:} For i = 1 to L$ ${R}_{n - i}^{′ ( j )} = {h}_{mn}^{- 1} {s}_{i}^{′} - {Q}_{n}^{( j )} , n ε N ( m ) \backslash {𝒩}_{i}^{′}$ ${R}_{n - i}^{′ ( j )} = {h}_{mn}^{- 1} {s}_{i}^{′} - {Q}_{n}^{( j )} , n = {𝒩}_{i}^{′}$ $end For i$ $A 4.1 \text{:} {W}_{mn}^{( j )} ( {R}_{n}^{( j )} ) = {W}_{mn}^{( j - 1 )} ( {R}_{n}^{( j )} ) + {v}_{0}$ $A 4.2 \text{:} For i = 1 to L$ ${W}_{mn}^{( j )} ( {R}_{n - i}^{′ ( j )} ) = {W}_{mn}^{( j - 1 )} ( {R}_{n - i}^{′ ( j )} ) + {v}_{1}$ $end For i$ $A 5.1 \text{:} {W}_{n}^{( j )} ( {R}_{n}^{( j )} ) = {W}_{n}^{( j - 1 )} ( {R}_{n}^{( j )} ) + {v}_{0}$ $A 5.2 \text{:} For i = 1 to L$ ${W}_{n}^{( j )} ( {R}_{n - i}^{′ ( j )} ) = {W}_{n}^{( j - 1 )} ( {R}_{n - i}^{′ ( j )} ) + {v}_{1}$ $end For i$ $end For m$ $A 6 \text{:} {\overline{c}}_{n}^{( j )} = GFmax ( {W}_{n}^{( j )} )$ $A 7 \text{:} if ( {\overline{c}}_{n}^{( j )} \times {H}^{T} = 0 ) SKIP$ $end For j$ $Output = {\overline{c}}_{n}^{( j )}$

The method of the invention, above, comprises Iₜ decoding iterations. In the following, the method is described at each iteration j.

Before, the Iₜ decoding iterations an initialization step, Initialization, comprises the sub-steps of:

determining a LLR vector Lₙ=(Lₙ[0], Lₙ[1], . . . , Lₙ[q−1]) of a n^{th} symbol in a sequence of N non-binary noisy symbols;

initializing a vector of APP vectors Wₙ⁽⁰⁾ to the LLR vector Lₙ and initializing a matrix Wₘₙ⁽⁰⁾ to an all-zero matrix, said matrix Wₘₙ^{(j)} being the intrinsic information from the check node m.

In steps A1.1 and A1.2 each variable node V, connected to a check node Cₘ is configured for determining a most reliable symbols Qₙ^{1(j)} and at least one symbol which is at least a p^{th} most reliable symbol Qₙ^{p(j)}, with p≧2 for obtaining a vector of dc most reliable symbols. FIG. 1b illustrates the principles of these steps A1.1 and A1.2.

In particular steps A1.1 and A1.2 search the extrinsic information of the most reliable symbols ΔWₙ^{(j)}(max₁) , and their associated hard decision symbols Qₙ^{(j)} and Q′ₙ^{(j)}.

Furthermore, each variable node n=0, . . . , d_{c}−1 is configured for determining (the most reliable symbols Qₙ^{(j)} and the second most reliable symbol Q′ₙ^{(j)} and their corresponding extrinsic reliability ΔWₙ^{(j)}, ΔW′ₙ^{(j)} so that at a check node m the list of L+1 test vectors are built by replacing symbol Qₙ^{(j)} by the second most reliable symbol Q′ₙ^{(j)} in at most η≦L locations were the differences between ΔWₙ^{(j)} and ΔW′ₙ^{(j)} are the smallest, with ΔWₙ^{(j)}=Wₙ^{(j)}−Wₘₙ^{(j)}.

Based on the dc most reliable symbols, each check node Cₘ is configured for determining:
in step A3.1, a first symbol to be voted (selected) Rₙ^{0(j)} based on the vector of d_{c} most reliable symbols passed by the variable nodes connected to him in the bipartite graph;
in step A3.2, a list of i=1, . . . , L second symbol to be voted (selected) Rₙ^{i(j)} based on a list of L+1 test vectors defined as a combination of d_{c} symbols with a restriction according to which at most η of these d_{c} symbols are a p^{th} most reliable symbol Qₙ^{p(j)} with p≧2, and at least d_{c}−η of these d_{c} symbols are a most reliable symbol Qₙ^{(j)}.

FIG. 1c and FIG. 1d illustrate the principles of steps A3.1 and A3.2. On these figures, a check node is connected to three variable nodes x; y, z. A check node receives dc vectors of p elements from dc different variables nodes and computes dc vectors of p symbols. The information computed by the check node is sent to dc different variable nodes.

It can be seen that comparatively with Algorithm 1, each check node performs more operations than a check node of Algorithm 1. Further, step A3.1 is the same as A3 in algorithm 1.

Furthermore, each variable node is configured for determining in steps A1.1 and A1.2 the most reliable symbols Qₙ^{(j)} and the second most reliable symbol Q′ₙ^{(j)} and their corresponding extrinsic reliability ΔWₙ^{(j)}, ΔW′ₙ^{(j)} so that at a check node in steps A2.1 and A2.2 the list of L+1 test vectors are built by replacing symbol Qₙ^{(j)} by the second most reliable symbol Q′ₙ^{(j)} in at most η≦L locations were the differences between ΔWₙ^{(j)} and ΔW′ₙ^{(j)} are the smallest, with ΔWₙ^{(j)}=Wₙ−Wₙₘ.

The method of the invention also comprises a step consisting in that a sorter unit is configured for sorting in step A1.3 the differences of extrinsic reliability ΔWₙₘ^{(j)}−ΔW′ₙₘ^{(j)} from the highest value to the lowest value for obtaining a sequence [symbol] ′ of L sorted indices n, the sequence [symbol] ′ comprising the η locations where Qₙ^{(j)} is replaced by Q′ₙ^{(j)} in the L+1 test vectors.

In particular, step A1.3 sorts ΔWₘₙ^{(j)}−ΔW′ₙₘ^{(j)} in increasing order, where n ∈ [symbol] (m). Hence, the first values after the sorting are the ones with least difference between, the reliability of Qₙ^{(j)} and Q′ₙ^{(j)} symbols. Finally, step A1.3 stores the sorted n indices in [symbol] .

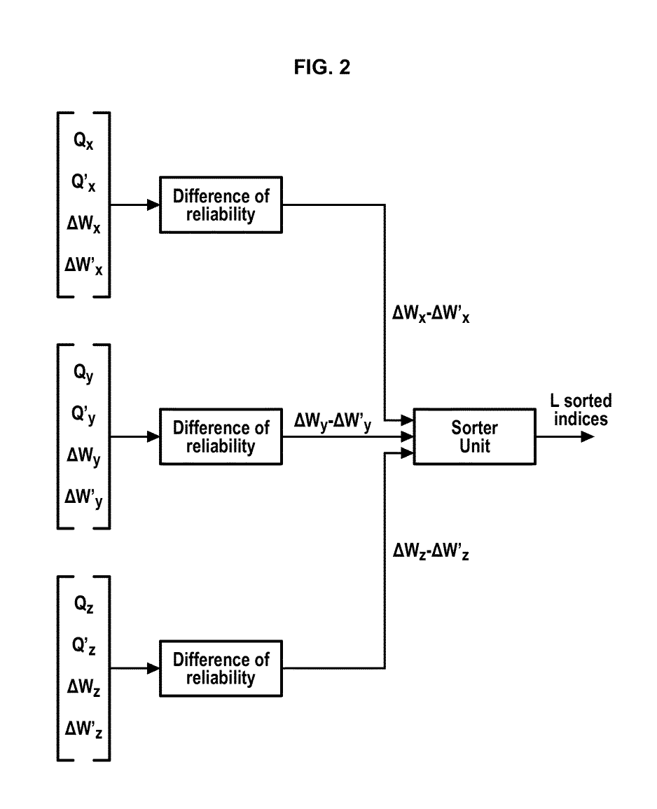

FIG. 2 illustrates the principles of step A1.3 for generating L sorted indices. On this figure, a check node is connected to three variable nodes x, y and z.

Additionally, each variable node is further configured for computing in steps A4.1 and A4.2 an intrinsic information Wₘₙ^{(j)} from check node counting the votes of Rₙ^{(j)} and of Rₙ^{i(j)} with the respectively amplitude voting v₀, v₁.

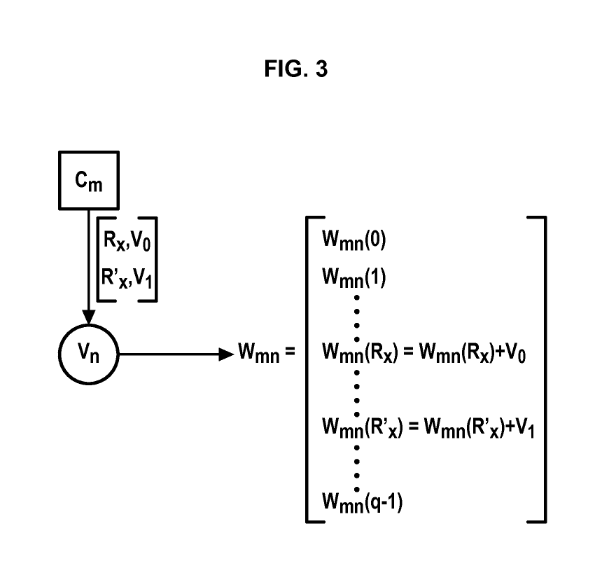

FIG. 3 illustrates the principles of steps A4.1 and A4.2 on which a variable node Vₙ counts the vote in Wₙₘ according to the information received from a check node Cₘ. In this example, the count for the symbols are increased in v₀, and v₁ respectively.

Furthermore, each variable node taking as input the LLR vector and the vector Wₘₙ^{(j)} combines (A4.1, A4.2) the previous vector Wₘₙ^{(j-1)}, the voting symbols Rₙ^{0(j)} and of R′ₙ^{(j)} and the voting amplitudes v₀, v₁ through a function F₁ for obtaining the vector defined as the intrinsic information Wₘₙ^{(j)}.

The function F₁ can be a simple summation of the values of the previous vector Wₘₙ^{(j-1)} at indices indicated by the voting symbols Rₙ^{0(j)} and of Rₙ^{i(j)} and the voting amplitudes v₀, v₁.

Also, each variable node taking as input the LLR vector and the vector Wₙ^{(j)} combines in steps A5.1, A5.2 the previous vector Wₙ^{(j-1)}Wₘₙ^{(j-1)}, the voting symbols Rₙ^{(j)} and of R′ₙ^{(j)} and the voting amplitudes v₀, v₁ through a function F₂ for obtaining the vector Wₙ^{(j)}.

The function F₂ can be a simple summation of the values of the previous vector Wₙ^{(j-1)} at indices indicated by the voting symbols Rₙ^{(j)} and of R′ₙ^{(j)} and the voting amplitudes v₀, v₁.

Steps A2.1, A3.1, A4.1 and A5.1 from Algorithm 2 are the same as A2, A3, A4 and A5 in Algorithm 1. These steps are performed based on the most reliable symbols. Steps A2.2, A3.2, A4.2 and A5.2 are performed with the L test vectors from the considered set of Qₙ^{(j)} and Q′ₙ^{(j)} symbols. Steps A2.2, A3.2, A4.2 and A5.2 are performed with the L+1 test vectors from the considered set of Qₙ^{(j)} and Q′ₙ^{(j)} symbols. Step A2.2 performs the syndrome computation for the L+1 test vectors (s′ᵢ), formed by one symbol [symbol] and d_{c}−1 symbols Qₙ^{(j)}. Step A3.2 calculates the candidates of the voting process, R′ₙ₋ᵢ^{(j)}, according to each one if the L+1 test vectors. Steps A4.2 and A5.2 are similar to steps A4 and A5 of algorithm. The main difference is that in the first one the voted candidates are R′ₙ₋ᵢ^{(j)} instead of Rₙ^{(j)}. One can note that there are two amplitudes for the votes v₀, v₁. As it can been explained earlier, the constraint v₀>v₁ must be fulfilled, because Rₙ^{(j)} is computed with Qₙ^{(j)} symbols, so it is more reliable than R′ₙ₋ᵢ^{(j)}, which is computed with both Qₙ^{(j)} and Q′ₙ^{(j)} symbols.

### Architecture of a Decoder for Implementing the Method of the Invention

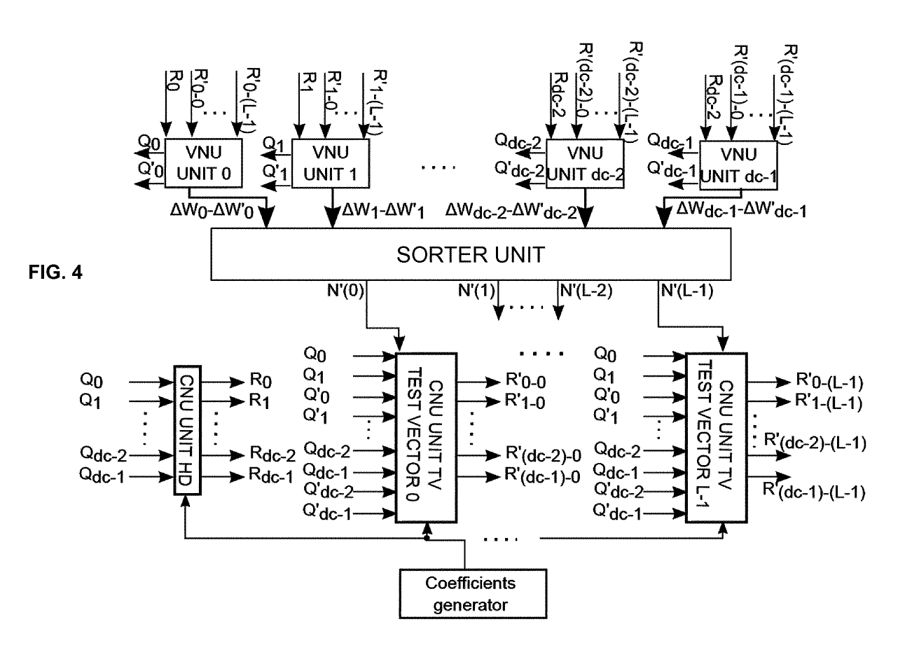

A decoder for implementing the method of the invention is now described in relation to FIG. 4.

On this figure, a diagram of the complete architecture is described. Three main parts can be distinguished: i) VNU units, ii) CNU units and iii) the sorter unit. The decoder has dc VNU units. Each VNU unit computes Qₙ^{(j)} and Q′ₙ^{(j)} symbols which are the input for CNU units, by using Rₙ^{(j)} and R′ₙ^{(j)} incoming symbols (with i from 0 to L). In addition, VNU units calculate ΔWₙₘ^{(j)} and ΔW′ₙₘ^{(j)} and perform the subtraction (ΔWₙₘ^{(j)}−ΔW′ₙₘ^{(j)}), which is used as input of the sorter unit. So, VNU units implement steps A1.1, A1.2, A4.1, A4.2, A5.1 and A5.2 from Algorithm 2. The sorter unit receives dc ΔWₙₘ^{(j)}−ΔW′ₙₘ^{(j)} values and looks for the L smallest values (the elements which are added to the enlarged list are the ones with the smaller difference between the reliabilities of Qₙ^{(j)} and Q′ₙ^{(j)}). The sorter outputs are the indexes of the L elements with the smallest ΔWₙₘ^{(j)}−ΔW′ₙₘ^{(j)} values within the dc inputs. This part of the architecture implements step A1.3 and due to its complexity and relative novelty it is explained at the end of the section, separately from the rest. Finally, two different kinds of CNU units are found: the ones that compute only Qₙ^{(j)} symbols (CNU unit HD) and the ones that compute test vectors with both Qₙ^{(j)} and Q′ₙ^{(j)} (CNU unit test vector (TV)). The decoder has just one CNU unit HD and L CNU units TV. Hardware resources for computing hₘₙ coefficients are shared between both HD and TV units. CNU unit HD implements steps A2.1 and A3.1 steps, while the L CNU units TV implement steps A2.2 and A.3 from Algorithm 2.

### CNU Units

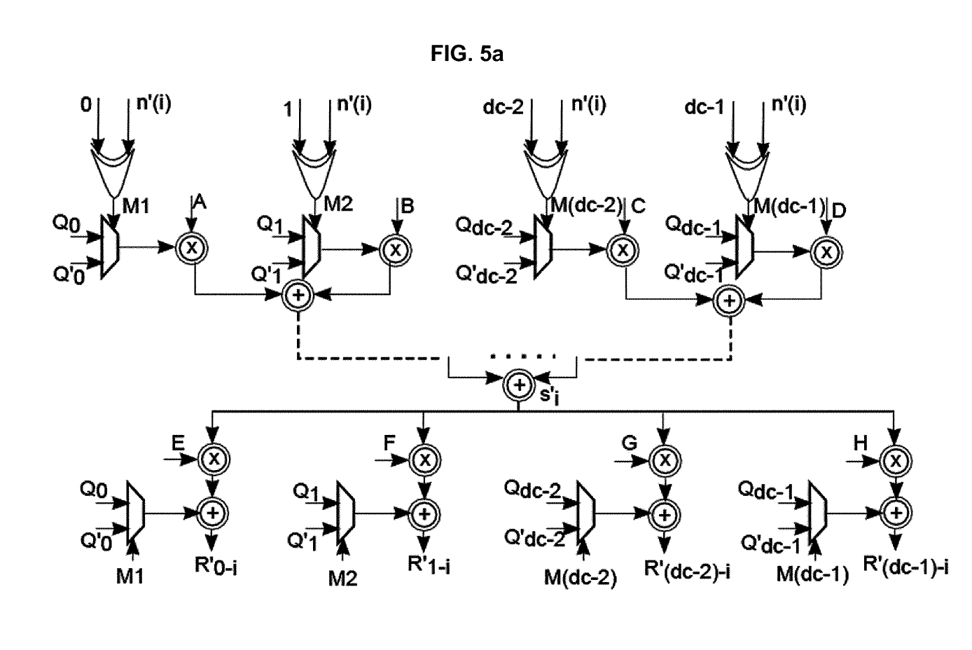

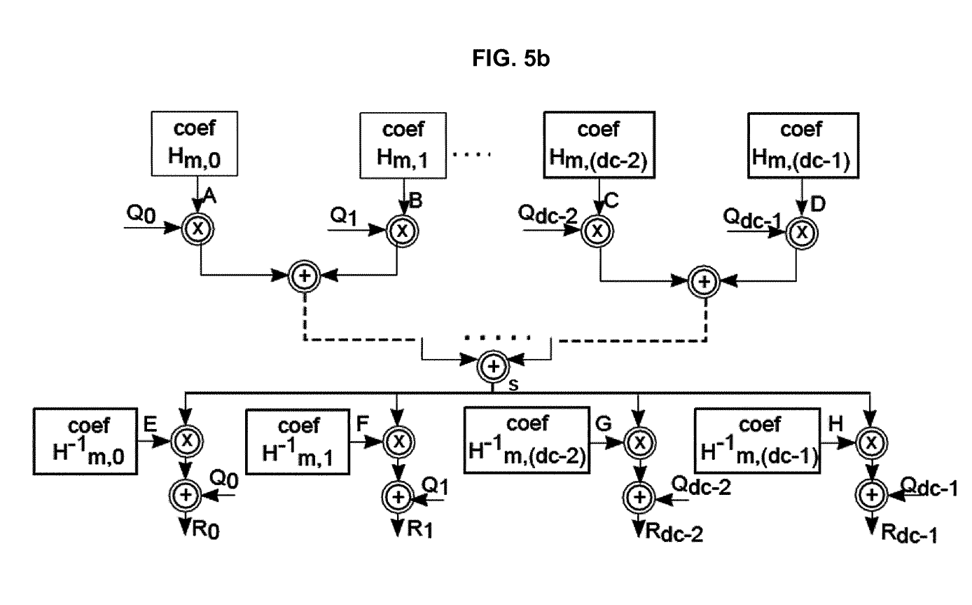

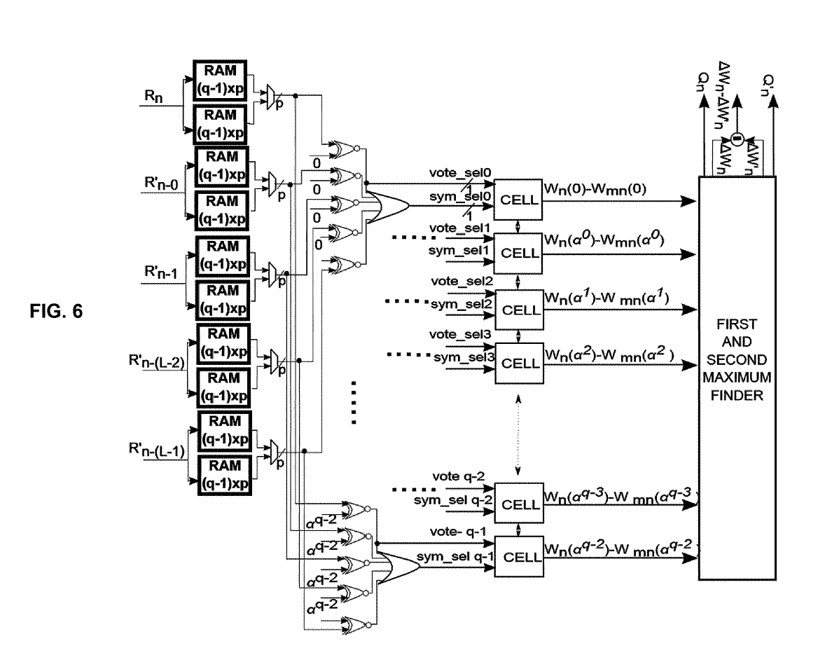

FIG. 5a and FIG. 5b illustrate an embodiment of the CNU units. All the arithmetic resources included in these units are defined over GF(q). FIG. 6a includes the CNU unit HD, which is the same as the one applied in [18] for the ES-GBFDA architecture. The coeff Hₘₙ and coeff H′ₘₙ blocks generate in each clock cycle the coefficients hₘₙ and h′ₘₙ required by steps A2.1, A2.2, A3.1 and A3.2. These blocks are implemented by two ROMs and one counter, which are not included in the figure for simplicity. The hₘₙ coefficients are multiplies by the Qₙ^{(j)} inputs. The outputs of the multipliers are added using tree architecture, generating the hard decision syndrome s (step A2.1). The syndrome s is multiplied by hₘₙ⁻¹ coefficients and the result is added to Qₙ^{(j)} symbols to compute Rₙ as indicated in step A3.1.

FIG. 6b represents the CNU unit for a test vector i. This block performs the same arithmetic operations as the one in FIG. 6a, the main difference is that not all the symbol inputs are the most reliable ones (Qₙ^{(j)}). To know in which of the dc possible locations Qₙ^{(j)} has to be changed by Q′ₙ^{(j)}, a comparison with the incoming n′(i) index from the sorter unit must be done. The comparison is done by means of an XOR gate. If the index of a location is equal to n′(i), the output of the XOR gate is zero and Q′ₙ^{(j)} is with the multiplexor; in other case, Qₙ^{(j)} is selected. Note that L CNU units as the one in FIG. 6b are necessary to implement steps A2.2 and A3.2 (to compute s′ᵢ and R′ₙ₋ᵢ). Moreover, it is important to remark that the hardware resources for the generation of hₘₙ and hₘₙ⁻¹ coefficients are shared between all the CNU units. In other words, just dc coeff Hₘₙ blocks and dc coeff Hₘₙ⁻¹ blocks are needed in the whole decoder, and their outputs are wired to all the CNU units as illustrated on FIG. 5.

### VNU Units

FIG. 6 illustrates an embodiment of a VNU unit. The VNU unit comprises four different parts: i) ping-pong memories, ii) logic for selecting the active cells, iii) VNU cells, and iv) first and second maximum finder logic.

Each VNU unit has 2×(L+1) RAMs that store Rₙ^{(j)} and R′ₙ₋ᵢ symbols. A single RAM stores (q−1)Rₙ^{(j)} (or R′ₙ₋ᵢ) symbols that correspond to the information of one sub-matrix. Rₙ^{(j)} and R′ₙ₋ᵢ symbols are represented with p bits because q=2^{p.} Memories connected to the same input work in a ping-pong way, so during q−1 clock cycles one RAM is read and the other is written and for the next q−1 cycles memories work in the opposite way. This reduces the idle cycles of the decoder and increases its efficiency.

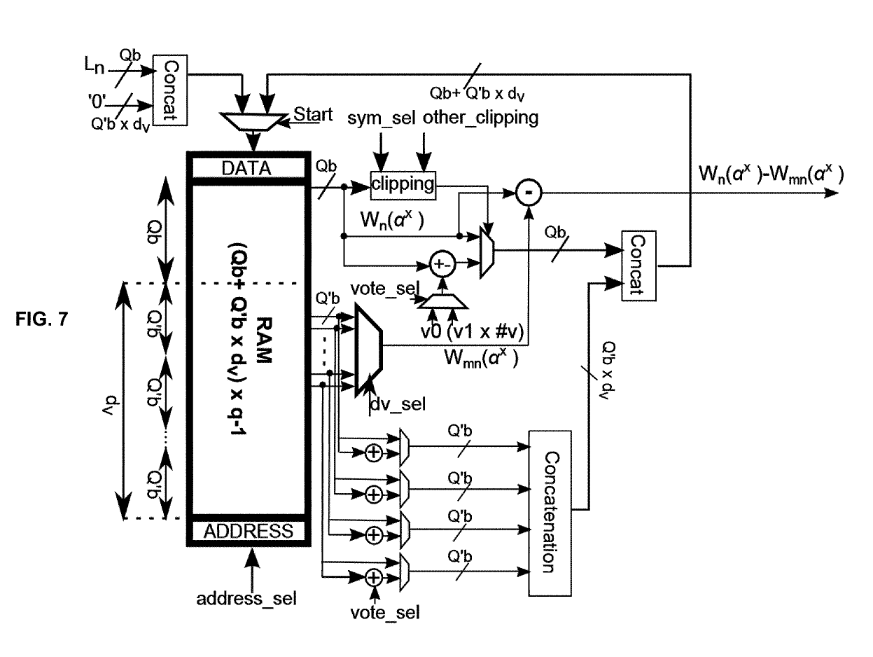

mThe logic for selecting the active cells generates sym_sel x which indicates if a VNU cell receives a vote or not. To compute sym_sel x of a cell x, all the Rₙ^{(j)} and R′ₙ₋ᵢ symbols (outputs of the ping-pong RAMs selected by the multiplexor) are compared with the symbol x associated to the cell, where x ∈ GF(q). These comparisons are implemented with XNOR gates, so if one of the symbols (Rₙ^{(j)} or R′ₙ₋ᵢ) is equal to x, the output of one of the XNOR gates will be one, indicating that the symbol x is voted. sym_sel x is computed by applying the OR operation to all the XNOR outputs that are compared to the symbol x. All the outputs of the XNOR gates (A bit) connected to R′ₙ₋ᵢ are also added (omitted on FIG. 7 for simplicity) to know the number of votes (#v) received from the enlarged list. In addition, the output of the XNOR gate connected to the most reliable candidate input (Rₙ^{(j)}) is used as vote_sel x. To sum up the logic for the cells works as follows: i) if vote_sel x equals one and sym_sel x is also active, the vote is generated by Rₙ^{(j)}, so the amplitude v₀ is selected in the cell; ii) is vote_sel x equals zero but sym_sel x is active, the vote is generated by R′ₙ₋ᵢ, so an amplitude proportional to v₁ (v₁∴#v) is selected in the cell; iii) otherwise, no vote is performed.

Each VNU unit has q cells that compute Wₙ(0)−Wₘₙ(0), Wₙ(α⁰)−Wₘₙ(α⁰), |Wₙ(α¹)−Wₘₙ(α¹) . . . , Wₘₙ(α^{q-1})−Wₘₙ(α^{q-2})|.

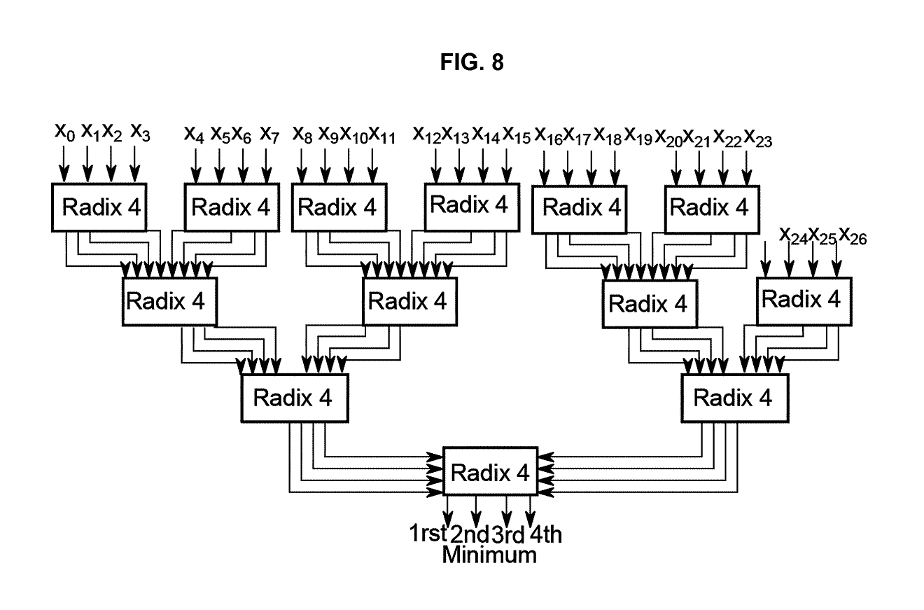

In FIG. 7, the architecture for one cell of the VNU unit is included. The number of bits for the quantization of Lₙ and Wₙ is Q′_{b}. The cell of the element α^{x} stores in each word of the RAM Wₙ(α^{x}) and Wₘₙ(α^{x}) for one value of n (and the dᵥ.values of check node Cₘ connecred to this variable node Vₙ, so the length of the word is Q_{b}+Q′_{b}×dᵥ. The memory has q−1 words because stores the information for q−1 different values of n. During initialization, the RAM is filled with the Lₙ values concatened with dᵥ×Q′_{b} zeros. After that, the RAM stores the updated information for Wₙ(α^{x}) (steps A5.1 and A5.2) and the dᵥ different values of Wₘₙ(α^{x}) (steps A4.1 and A4.2). The update of Wₙ(α^{x}) depends on: i) the value of sym_sel, ii) the detection of clipping in other cells of the same VNU unit, iii) the detection of clipping in the own cell and iv) value of vote_sel. If the cell detects a vote (sym_sel is active) and no clipping is detected, in the own cell, Wₙ(α^{x})=Wₙ(α^{x})+v_{y}. If the cell does not detect a vote and clipping is detected in other cells, Wₙ(α^{x})=Wₙ(α^{x})−v_{y}. In other cases, Wₙ(α^{x}) remains the same. v_{y} can take two values: v₀ (step A4.1 and A5.1) or v₁×#v (step A4.2 and A5.2). A ROM with depth L stores the different v₁×#v possible values, in order to avoid a multiplier. The ROM is not included in FIG. 8. On the other hand, the signal dv_sel selects the corresponding Wₘₙ(α^{x}) from the dᵥ possible values. Wₘₙ(α^{x}) is required for the computation of Wₙ(α^{x})−Wₘₙ(α^{x}). In addition, the Wₘₙ(α^{x}) is increased by v_{y} if sym_sel=1, to take into account the amplitude of the vote made in the current iteration (steps A4.1 and A4.2). Note that the symbols of the adders controlled by vote_sel in FIG. 8 just a schematic way of representing an adder and a multiplexor controlled by vote sel that selects v₀ or v₁×#v. Both Wₙ(α^{x}) and the dᵥWₘₙ(α^{x}) updated values are concatenated and stored again in the RAM.

The outputs of q cells (Wₙ−Wₘₙ) are the inputs of the maximum finder unit as it is shown in FIG. 7. This block looks for: the first maximum (ΔWₙ^{(j)} in step A1.1), the second maximum (ΔW′ₙ^{(j)} in step A1.2) and its associated GF symbols (Qₙ^{(j)} and Q′ₙ^{(j)}) between the q inputs. The architecture applied for this block can be found in [20]. Finally, ΔWₙ^{(j)} and ΔW′ₙ^{(j)} outputs are subtracted to compute the difference between the highest and the second highest reliability values. The sorter unit (see FIG. 5) generates L n′(i) indices for the L minimums between the d_{c} ΔWₙ^{(j)}−ΔW′ₙ outputs of the VNU units. This sorted will be explained below.

The latency equation for the whole decoder is the same as the one in [18]; however, if the same frequency wants to be reached the number of pipeline stages must be increased. The latency of the decoder is (q−1+pipeline)×dᵥ×(#iterations+1)+(q−1+pipeline) clock cycles. Computing each sub-matrix takes (2^{q}−1) but the pipeline delay has to be added, so each sub-matrix needs (q−1+pipeline) clock cycles. As there are dᵥ sub-matrices, each iteration needs (q−1+pipeline)×dᵥ clock cycles. We have to add one extra iteration to the total number of iterations for the initialization and (q−1+pipeline) clock cycles are needed to get the values of the decoded codeword after the iterative process.

### Sorter Unit: L-Minimum Finder in a dc Element List

The proposed ascendant sorter unit can be seen as an L-minimum finder. The architecture is based on the one from [20] but instead of looking for two minimums, it looks for L minimums. The main difference between this proposal and the one in [20] is that we do not apply masks to compute the minimums different from the absolute one. The fact of avoiding masks reduces the critical path at a cost of increasing some hardware resources. We describe an architecture for the sorter unit for L=4 and dc=27, but it can be easily generalized. In addition, the selection of the radix for each one of the stages is not optimized as the objective is just to show that there is a possible solution to implement the ascendant sorter unit with moderated area and continuous processing (each clock cycle a new group of elements can be sorted, after the latency generated by the pipeline with the first input).

FIG. 8 illustrates the architecture of a sorter unit according to an embodiment of the invention for the finder with L=4 and dc=27. As happens with the architecture in [20] for the two minimum finder, we distinguish two different kind of stages: I=0 and I>0. Stage 1=0 units just involves L inputs, while I>0 computes 2×L inputs.

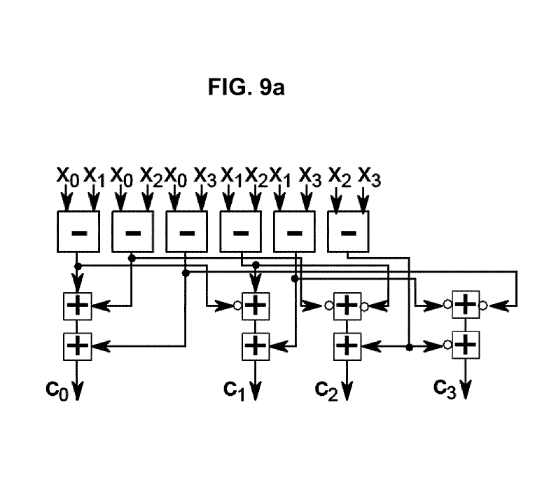

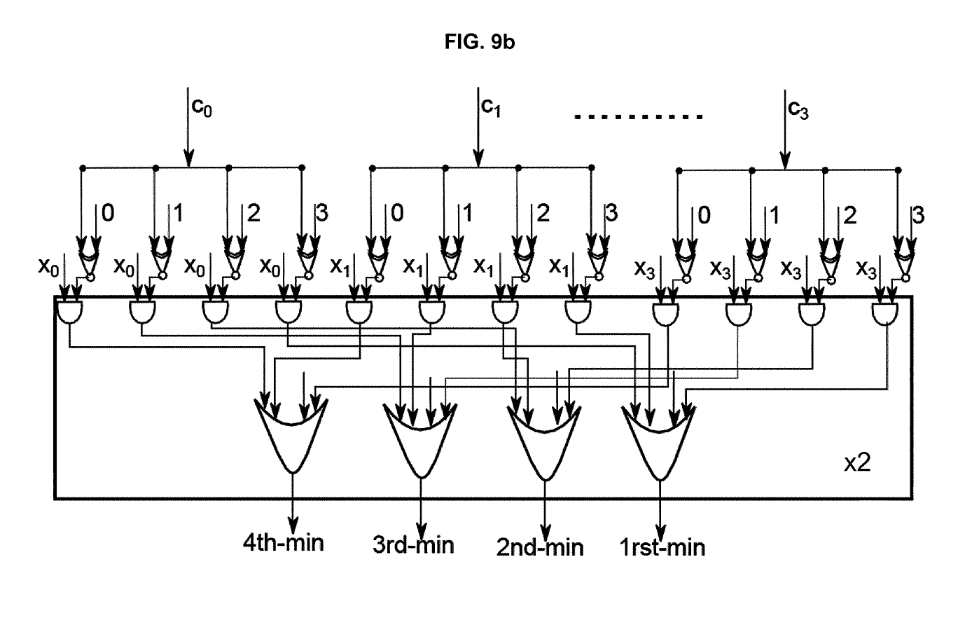

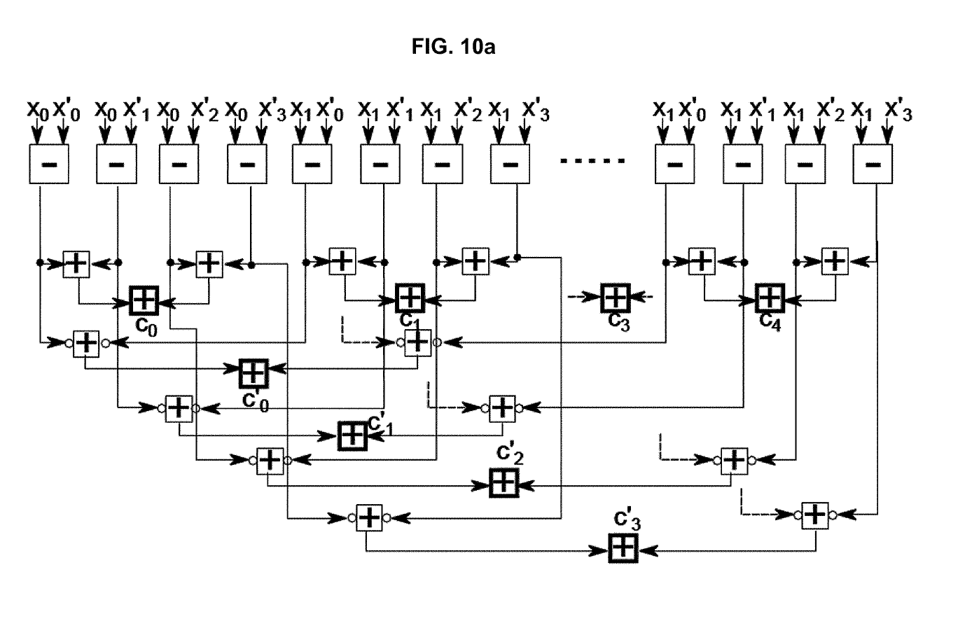

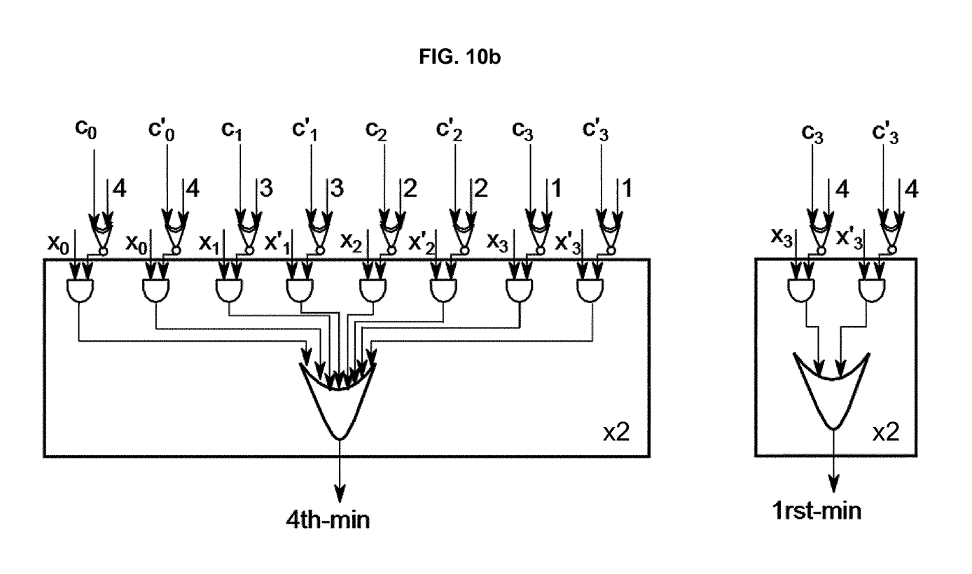

The architecture for one unit of stage I=0 is illustrated on FIG. 9a and FIG. 9b. First, comparisons between the L incoming values (xn) are performed (FIG. 10a). The total number of comparisons that must be calculated are (L−1)×L, however, just (L−1)×L/2 are required to compute the comparisons, because the other (L−1)×L/2 values can be obtained by applying the complement to the output of the subtracters (performed by NOT gates). After the comparisons, the number of cases in which the input xₙ is a minimum is counted, cₙ. For calculating each cₙ, log₂(L) adders are needed (for the case of L=4, two adders of two bits). The result of the count, cₙ, is compared with all the possible solutions by means of XNOR gates (FIG. 10b). As an example, if c₀ is the minimum compared to two elements in a list of four elements: the outputs of the XNOR gates whose input is connected to zero (is not the minimum) one (is minimum compared to one element) and three (is the absolute minimum) are zero; and the output of the XNOR gate whose input is two (minimum compared to two elements) is equal to one. So, the outputs of the XNOR gates with input cₙ, will set just one AND gate output to xₙ. Following the previous example, the AND gate connected to the XNOR with output equal one (the one compared with two), will have as result x₀; the rest of the AND gates (compared with zero, one and three) will have zero output. Finally, an OR operation is applied to the outputs of the AND gates connected to XNOR gates with the same constant input value. In FIG. 10b, the output of the AND gates connected to XNOR gates whose constant input is equal to three are wired to the same OR gate, the one that computes the first minimum (because if the value is minimum compared to three elements in a list of four, the selected element will be the first minimum). The same reasoning can be followed for the rest of the minimums. Note that the AND and OR gates are duplicated (x2 in FIG. 10b) because we need to output not just the sorted magnitude, but also the corresponding indexes. The architecture for the units of stage I>0 is illustrated on FIG. 10. In this case, there are 2×L inputs, which can be seen as two L sorted sequences. The fact of having two groups of L elements already sorted reduces the number of required comparisons (from (2×L)×(2×L−1) to 2×L²), because comparisons between elements of the same group can be avoided. A total of L² substracters are required, because as happened with the unit of stage I=0 the other L² values are the complement of the ones computed by the subtractions. To count the number of comparisons (cₙ or c′ₙ) in which an input xₙ is less than the x′ₙ elements (and vice versa) log₂(L+1) adders are required (for the case of L=4, two adders of two bits and one adder of three bits are needed). As the elements inside each one of the two groups of inputs are sorted, some a priori information is known. For example, to compute the first minimum, just the first minimums of each group have to be taken into account and the one whose cₙ or c′ₙ equals to L will be the absolute minimum. On contrary, for the L-th minimum all the incoming inputs should be take into account. FIG. 10 includes an example of how to compute the L-th minimum for L=4. The 4th minimum output can be: i) the 4th minimums of the input groups (x₀ and x′₀) with c₀ or c′₀ equal to 4 (which are minimum compared to the other entire group); ii) the 3^{rd} minimums of the input groups (x₁ and x′₁) which are minimum compared to three of the elements of the other group (c₁=3 or c′₁=3); iii) the 2^{nd} minimum of the input groups (x₂ and x′₂) which are minimum compared to two of the elements of the other group (c₂=2 or c′₂=2); or iv) the 1rst minimums (x₃ and x′₃) that are minimum compared to the 4^{th} minimum of the other list (c₃=1 or c′₃=1). The computation and hardware resources for the rest of the minimums between the lrst one and the L-th one can be derived easily generalizing the examples. AND and OR gates are duplicated to sort both magnitude and indexes.

In the invention, the decoder of FIG. 5, the output of the n′(i) indexes are required to elaborate the test vectors. With the proposed architecture, the computation of the n′(i) indexes are done in parallel avoiding recursive solutions that would increase considerably the number of clock cycles per iteration of the decoder.

### Implementation Results and Comparison

We here below give estimated results of area and throughput for the decoder architecture described above.

To perform the estimation, analytical methods as the ones in [21] were applied. To ensure that a fair comparison with other works is done, we overestimate some hardware resources to provide an upper bound in both area and critical path. For example, the area of the first and second maximum finder in FIG. 7 was considered the same as the area for the L-minimum finder with L=4. For comparison proposals, a (837,726) code, with quasi-cyclic matrix H_{K=124,N=837)} over a field GF(q) with q=32, d_{c}=27 and dᵥ=4 was considered. The quantization scheme applied to Algorithm 2 is Q_{b}=7 and Q′_{b}=5. Note that as the optimized amplitudes for the votes of this code are v₀=0.5 and v₁=0.25 two extra bits are required compared to ES-GBFDA, which works just with integer vote amplitudes and cannot differentiate soft decision in the votes (all the votes have the same amplitude).

On the other hand, the MV-SF architecture adds hardware to compute the test vectors, increasing the length of the critical path compared to ES-GBFDA in [18]. The number of gates of the critical path is increased at the check node for the selection of the test vectors (FIG. 4b) and at the sorter unit (FIG. 9). Hence, to achieve a similar frequency to the ES-GBFDA architecture [18] it is necessary to double the number of pipeline stages (pipeline=10). Four extra pipeline stages at the sorter unit and one extra pipeline stage at the check node are necessary to keep the critical path equal to 22 gates.

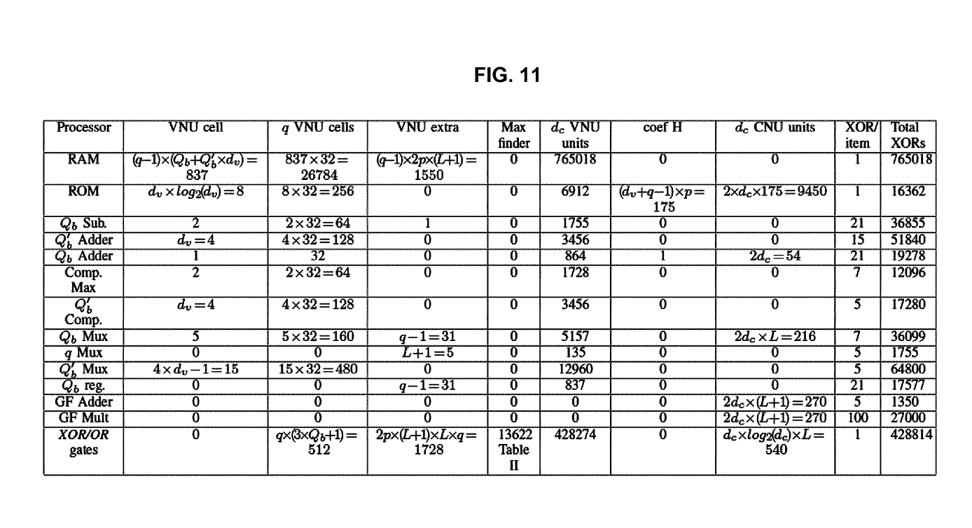

Although this critical path is two gates longer than the one in [18], the effect of routing is bigger than the one from the logic depth, so we can assume frequency ˜238 MHz without introducing a big error in the estimation. Hardware resources for MV-SF decoder with the previous parameters can be found in the table of FIG. 11.

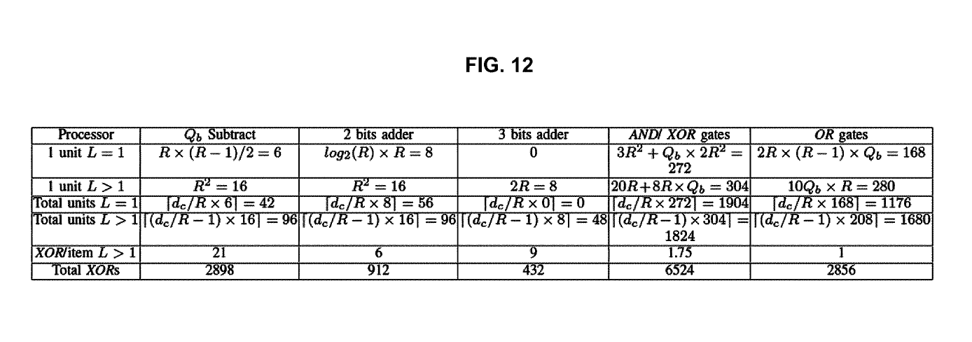

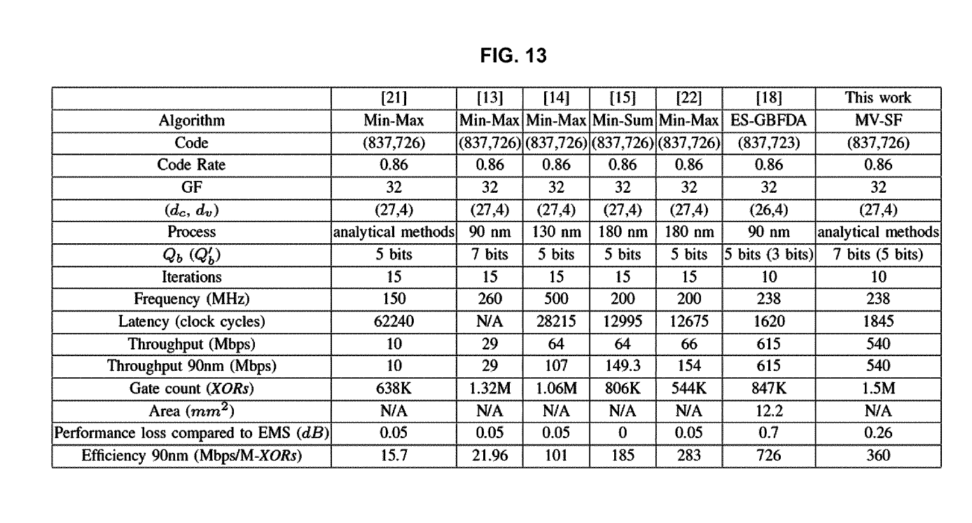

In the table of FIG. 12, results for NB-LDPC architectures based on different algorithms, including the one in this paper, are summarized. Note that all the codes in table of FIG. 13 have the same sizes, i.e. same number of coded symbols N=837, and same number of non-binary parity check equations M=124. The code used for the ES-GBFDA [18] has 3 more redundant rows than the other code. It is important to remark that as different algorithms are implemented in each reference, different coding gains are obtained by each decoder. For this reason, we also include the performance loss of each one of the decoders, taking as reference the performance of EMS. Performance degradation in coding gain is difficult to take into account in the efficiency parameter, so it is not included. The efficiency parameter is computed as throughput(Mbps)=area(MXORS), following the description of efficiency from [13] and [14], [15].

Comparing the ES-GBFDA decoder to the one for implementing the method of the invention, we increase area 1.5M/847K=1.77 times with an slightly lower throughput (540 Mbps instead of 615 Mbps).

The decoder of Algorithm 2 is 726/360=2 times less efficient than the one based on ES-GBFDA in [18] but it reaches a non-negligible coding gain of 0.44 dB. A direct mapping architecture of Algorithm 2 requires L+1 times the area of ES-GBFDA (L for the less reliable test vectors and one for the most reliable one), which is 4.23 MXOR. Hence, our proposal is 4.23M/1.5M=2.82 times less area consuming than a direct mapping architecture with 12% less throughput. In terms of efficiency, a direct mapping architecture 615 Mbps=4.23 MXORs=145) is more than two times less efficient that the proposal of this work, with the same coding gain.

To the best knowledge of the authors, the architecture in [15] is the most efficient one based on Min-Sum algorithm.

Compared to this architecture, the decoder of the invention requires 1.5M/806K=1.86 times more area, but reaches a throughput 540/149=3.62 times higher. The decoder for Algorithm 2 is 360=185=1.9 times more efficient compared to the one in [15] based on Simplified Min-Sum, but a difference of 0.26dB in coding gain should be taken into account. Regarding to Min-Max architectures, we compare to the most efficient one, [22] (other efficient architectures are included in the table of FIG. 14. The architecture based on Min-Max proposed in [22] is 1.5M/0.54M=2.75 times smaller than the one introduced in this paper. However, our proposal reaches a throughput 540/154=3.5 times higher than the Min-Max decoder in [22]. In terms of efficiency, the architecture based on Algorithm 2 shows 27% efficiency gain compared to the one based on Min-Max, at the cost of 0.21 dB of performance loss.

To sum up, the architecture based the method of the invention has 1.86 and 2.75 times more area than the ones based on EMS or Min-Max, but reaches a throughput 3.5 times higher. MV-SF introduces 0.26dB of performance loss compared to EMS and 0.21 dB compared to Min-Max.

### REFERENCES

[1] M. Davey and D. J. MacKay, “Low density parity check codes over GF(q)”, IEEE Commun. Letter, vol. 2, pp. 165-167, June 1998.

[2] L. Barnault and D. Declercq, “Fast decoding algorithm for LDPC over GF(2^{q})”, Proc. Info. Theory Workshop, pp. 70-73, Paris, France, March 2003.

[3] H. Wymeersch, H. Steendam and M. Moeneclaey, “Log-domain decoding of LDPC codes over GF(q),” Proc. IEEE Intl. Conf. on Commun., pp. 772-776, Paris, France, June 2004.

[4] C. Spagnol, E. Popovici and W. Marnane, “Hardware implementation of GF(2^{m}) LDPC decoders”, IEEE Trans. on Circuits and Syst.-I, vol. 56, no. 12, pp. 2609-2620, December 2009.

[5] D. Declercq and M. Fossorier, “Decoding algorithms for nonbinary LDPC codes over GF(q),” IEEE Trans. on Commun., vol. 55, pp. 633-643, April 2007.

[6] C. Poulliat, M. Fossorier and D. Declercq, “Design of regular (2,dc)-LDPC codes over GF(q) using their binary images”, IEEE Trans. Commun., vol. 56(10), pp. 1626-1635, October 2008.

[7] V. Savin, “Min-max decoding for non binary LDPC codes,” Proc. IEEE ISIT, pp. 960-964, Toronto, Canada, July 2008.

[8] A. Voicila, D. Declercq, F. Verdier, M. Fossorier and P. Urard, “Low-Complexity Decoding for non-binary LDPC Codes in High Order Fields”, IEEE Trans. on Commun., vol. 58(5), pp 1365-1375, May 2010.

[9] E. Boutillon and L. Conde-Canencia, “Bubble check: a simplified algorithm for elementary check node processing in extended min-sum non-binary LDPC decoders,” Electronics Letters, vol. 46, pp. 633-634, April 2010.

[10] X. Zhang and F. Cai, “Partial-parallel decoder architecture for quasi-cyclic non-binary LDPC codes,” Proc. of Acoustics Speech and Signal Processing (ICASSP), pp. 1506-1509, Dallas, Tex., USA, March 2010.

[11] D. Zhao, X. Ma, C. Chen, and B. Bai, “A Low Complexity Decoding Algorithm for Majority-Logic Decodable Nonbinary LDPC Codes,” IEEE Commun. Letters, vol. 14, no. 11, pp. 1062-1064, November 2010.

[12] C. Chen, B. Bai, X. Wang, and M. Xu, “Nonbinary LDPC Codes Constructed

Based on a Cyclic MDS Code and a Low-Complexity Nonbinary Message-Passing Decoding Algorithm,” IEEE Commun. Letters, vol. 14, no. 3, pp. 239-241, March 2010.

[13] Y.-L. Ueng, C.-Y. Leong, C.-J. Yang, C.-C. Cheng, K.-H. Liao, and S.-W. Chen, “An efficient layered decoding architecture for nonbinary QC-LDPC codes,” IEEE Trans. on Circuits and Systems I: Regular Papers, vol. 59, no. 2, pp. 385-398, February 2012.

[14] J. Lin and Z. Yan, “Efficient shuffled decoder architecture for nonbinary quasicyclic LDPC codes,” IEEE Trans. on Very Large Scale Integration (VLSI) Systems, vol. PP, no. 99, p. 1, 2012.

[15] X. Chen and C.-L. Wang, “High-throughput efficient non-binary LDPC decoder based on the Simplified Min-Sum algorithm,” IEEE Trans. On Circuits and Systems I: Regular

Papers, vol. 59, no. 11, pp. 2784-2794, November 2012.

[16] X. Zhang, F. Cai and S. Lin, “Low-Complexity Reliability-Based Message-Passing Decoder Architectures for Non-Binary LDPC Codes,” IEEE Trans. on Very Large Scale Integration (VLSI) Systems, vol. 20, no. 11, pp. 1938-1950, September 2011.

[17] F. Garcia-Herrero, M. J. Canet and J. Valls, “Architecture of generalized bit-flipping decoding for high-rate non-binary LDPC codes,” Springer Circuits, Systems, and Signal Processing, vol. 32, no. 2, pp. 727-741, April 2013.

[18] F. Garcia-Herrero, M. J. Canet, J. Valls, “Decoder for an Enhanced Serial Generalized Bit Flipping Algorithm,” IEEE International Conference on Electronics, Circuits and Systems (ICECS), pp. 412-415, Sevilla, Spain, December 2012.

[19] B. Zhou, J. Kang, S. Song, S. Lin, K. Abdel-Ghaffar, and M. Xu, “Construction of non-binary quasi-cyclic LDPC codes by arrays and array dispersions,” IEEE Trans. on Commun., vol. 57, no. 6, pp. 1652-1662, June 2009.

[20] L. Amaru, M. Martina, and G. Masera, “High speed architectures for finding the first two maximum/minimum values,” IEEE Trans. on Very Large Scale Integration (VLSI) Systems, vol. 20, no. 12, pp. 2342-2346, December 2012.

[21] X. Zhang and F. Cai, “Reduced-complexity decoder architecture for nonbinary LDPC codes,” IEEE Trans. on Very Large Scale Integration (VLSI) Systems, vol. 19, no. 7, pp. 1229-1238, July 2011.

[22] F. Cai; X. Zhang, “Relaxed Min-Max Decoder Architectures for Nonbinary Low-Density Parity-Check Codes,” IEEE Transactions on Very Large Scale Integration (VLSI) Systems, 2013.

[23] F. Garcia-Herrero, D. Declercq, J. Valls, “Non-Binary LDPC Decoder based on Symbol Flipping with Multiple Votes,” submitted to IEEE Commun. Letters, 2013.

1. A method for decoding a non-binary low density parity-check (NB-LDPC) code defined in a finite field of size q, which is a symbol flipping decoding method using multiple votes performed by the check node unit and transferred to the variable node unit,
the code can be displayed in a bipartite graph comprising at least one variable node Vₙ, n=0, . . . , N−1 and at least one check node Cₘ, m=0, . . . , M−1, said method comprising for each iteration j of Iₜ decoding iterations, the steps consisting in that:
each variable node Vₙ, connected to a check node Cₘ, is configured for determining (A1.1, A1.2) a most reliable symbol Qₙ^{1(j)} and at least one symbol which is at least a p^{th} most reliable symbol Qₙ^{p(j)}, with p≧2 for obtaining a vector of d_{c} most reliable symbols;
each check node Cₘ is configured for determining:
(A3.1) a first symbol to be voted Rₙ^{0(j)}=Rₙ^{(j)} based on the vector of d_{c} most reliable symbols passed by the variable nodes connected to him in the bipartite graph;
(A3.2) a list of i=1, . . . , L second symbols to be voted Rₙ^{i(j)} based on a list of L+1 test vectors defined as a combination of d_{c} symbols with a restriction according to which at most η of these d_{c} symbols are a p^{th} most reliable symbol Qₙ^{p(j)} with p≧2, and at least d_{c}−η of these d_{c} symbols are a most reliable symbol Qₙ^{1(j)}.

2. The method according to claim 1, wherein each variable node is configured for determining (A1.1, A1.2) the most reliable symbols Qₙ^{(j)} and the second most reliable symbol Qₙ^{2(j)}=Q′ₙ^{(j)} and their corresponding extrinsic reliability ΔWₙ^{(j)}, ΔW′ₙ^{(j)} so that at a check node (A2.1, A2.2) the list of L+1 test vectors are built by replacing symbol Qₙ^{(j)} by the second most reliable symbol Q′ₙ^{(j)} in at most η≦L locations were the differences between ΔWₙ^{(j)} and ΔW′ₙ^{(j)} are the smallest.

3. The method according to the preceding claim, wherein η≦L, the method comprising a step consisting in that a sorter unit is configured for sorting (A1.3) the differences of extrinsic reliability ΔWₙₘ^{(j)}−ΔWₙₘ^{2(j)} from the highest value to the lowest value for obtaining a sequence [symbol] ′ of L sorted indices n, the sequence [symbol] ′ comprising the η locations where Qₙ^{(j)} is replaced by Qₙ^{2(j)} in the L+1 test vectors.

4. The method according to claims 1 to 3, wherein each variable node is further configured for computing (A4.1, A4.2) an intrinsic information Wₘₙ^{(j)} from check node counting the votes of Rₙ^{0(j)} and of Rₙ^{i(j)} with the respectively amplitude voting v₀, v₂.

5. The method according to claims 1 to 4, comprising before the Iₜ decoding iterations an initialization step (Initialization) comprising the sub-steps of:
determining a LLR vector Lₙ=(Lₙ[0], Lₙ[1], . . . , Lₙ[q−1]) of a n^{th} symbol in a sequence of N non-binary noisy symbols;
initializing a vector of APP vectors Wₙ⁽⁰⁾ to the LLR vector Lₙ and initializing a matrix Wₘₙ⁽⁰⁾ to an all-zero matrix, said matrix Wₘₙ^{(j)} being the intrinsic information from the check node m.

6. The method according to the preceding claim, wherein each variable node taking as input the LLR vector and the vector Wₘₙ^{(j)} combines (A4.1, A4.2) the previous vector Wₘₙ^{(j-1)}, the voting symbols Rₙ^{0(j)} and of R′ₙ^{(j)} and the voting amplitudes v₀, v₁ through a function F₁ for obtaining the vector defined as the intrinsic information Wₘₙ^{(j)}.

7. The method according to the preceding claim, wherein the function F₁ is a simple summation of the values of the previous vector Wₘₙ^{(j-1)} at indices indicated by the voting symbols Rₙ^{0(j)} and of Rₙ^{i(j)} and the voting amplitudes v₀, v₁.

8. The method according to claim 5, wherein each variable node taking as input the LLR vector and the vector Wₙ^{(j)} combines (A5.1, A5.2) the previous vector Wₙ^{(j-1)}Wₘₙ^{(j-1)}, the voting symbols Rₙ^{0(j)} and of Rₙ^{i(j)} and the voting amplitudes v₀, v₁ through a function F₂ for obtaining the vector Wₙ^{(j)}.

9. The method according to the preceding claim, wherein the function F₂ is a simple summation of the values of the previous vector Wₙ^{(j-1)} at indices indicated by the voting) symbols Rₙ^{0(j)} and of Rₙ^{i(j)} and the voting amplitudes v₀, v₁.

10. A decoding apparatus comprising at least one variable node Vₙ and a at least one check node Cₘ, said decoder being configured for implementing a method for decoding a non-binary low density parity-check (NB-LDPC) code defined in a finite field of size q, according to one of the preceding claims.

11. A decoding apparatus according to the preceding claim, said apparatus being configured for implementing check node operations by means of L processing units configured dynamically to compute Rₙ^{i(j)}, with i=1, . . . , L, each one of the L processing units share 3×d_{c} inputs that correspond to the symbols Qₙ^{1(j)},Qₙ^{2(j)} and to the coefficients of the code, said inputs of each processing unit are combined by means of 2×d_{c} GF multipliers and 2×d_{c} GF adders, said processing units including all the logic necessary to compute L different syndromes as an intermediate step and a variable number of pipeline stages that may vary from 0 to log 2(d_{c})+2 depending on the speed of said processing unit.

12. A decoding apparatus according to the preceding claim, said apparatus being configured for implementing the method of claims 6, 7, 8 and 9 and comprising: i) a bank of memories that store Rₙ^{i(j)}, with i=0, . . . , L symbols, ii) q processors with a logic required to compare the symbols Rₙ^{i(j)}, with i=0, . . . , L, with the q elements of the Galois Field and determine the amplitude of the votes corresponding to that symbols; and iii) q cells that implement functions F₁ and F₂, the bank of memories being implemented with L RAM memories or a bank of L registers., the processors being implemented with L-XNOR gates of log 2(q) bits and L-OR gates of 1 bit to compare the input symbols, i.e., symbols Rₙ^{i(j)}, with i=0, . . . , L−1, with the q Galois Field elements and determine the amplitude of the votes, the cells including a logic necessary for implementing F₁ and F₂ and the storage resources for Wₘₙ^{(j)} and Wₙ^{(j)}.

13. A decoding apparatus according to claim 11, said apparatus comprising a sorter unit configured for obtaining the sequence [symbol] ′ of L sorted indices n according to the method defined in claim 3, the sorter unit including at least one sub-processors of radix L, each sub-processor including: i) one stage of comparators configured for performing all the possible combinations of the inputs; ii) a plurality of adders and a plurality of NOT gates configured for computing a summation of the output signals of the different comparators associated to the same input, the adders being configured for checking how many times a condition of greater than or less than is satisfied for each one of the inputs; iv) a plurality of logic gates configured for implementing a L different masks that allows ordering the inputs according to the information provided by the outputs of the adders, logic gates are XNOR, OR and AND gates.
